(19) United States
(12) Patent Application Publication
(10) Pub. No.: US 2009/0127677 A1
(43) Pub. Date: May 21, 2009

(54) Multi-Terminal Package Assembly For Semiconductor Devices

(76) Inventor: Jocel P. Gomez, Lapu-Lapu City (PH)

Correspondence Address: Kirton & McConkie;1800 Eagle Gate Tower, 60 East South Temple, P.O. Box 45120, Salt Lake City, UT, 84145-0120, US

(21) Appl. No.: 11/944,281

(22) Filed: Nov. 21, 2007

(51) Int. Cl. H01L 23/495; H01L 21/56

(52) U.S. Cl. 257/666; 438/123; 257/E21.505; 257/E23.031

(57) ABSTRACT

Semiconductor packages that contain leads with multiple terminals are described. The leads have a side terminal that can extend between a top terminal and a bottom terminal. The multiple terminals in the leads allow the semiconductor package to be connected to more than one external substrate and give the package multiple land pattern options. The semiconductor package can contain one or more dies that are connected to a lead frame in the package without the use of a clip. The back side of the die may be externally exposed from the package to help dissipate heat.

### FIELD

This application relates generally to packaging used for semiconductor devices (or semiconductor packages). More specifically, this application relates to semiconductor packages that comprise multiple terminals.

### BACKGROUND

Semiconductor processing builds hundreds of individual integrated circuit (IC) chips (or dies) on a wafer. These individual chips are then cut, tested, assembled, and packaged for their various uses. The packaging step in this processing can be an important step in terms of costs and reliability. The individual IC chip must be connected properly to the external circuitry and packaged in a way that is convenient for use with that circuitry that is part of a larger electrical circuit or system (such as a printed circuit board or PCB).

To increase their performance, some semiconductor device packages (or semiconductor packages) have been developed that are highly integrated, i.e., with more electronic components incorporated into a given size. For example, some semiconductor packages have been made that contain multi-chip modules (or two IC chips or dies in a single package). Wire bonding may electrically connect the die to individual leads that are then connected to the lead frame. A molding material may be used to encapsulate the integrated circuit die, leads, wire bonding, and other components to form the exterior of the package.

After the integrated circuit die has been produced and encapsulated in a semiconductor package, the resulting device may be used in an ever growing variety of electronic applications, such as disk drives, USB controllers, portable computer devices, cellular phones, power supplies, and so forth. In order to attach a semiconductor device in the package to an external electrical device, a terminal on the leads may be conductively bonded to a surface of an external substrate (e.g., a motherboard) of the electrical device.

However, conventional semiconductor packages may have several limitations. First, the wire bonding in semiconductor packages may be costly as well as unnecessarily increase the on-resistance (R_{DS}). Second, semiconductor packages that contain two (or more) IC dies may require a clip to connect the dies to the lead frame. Such a clip may increase production complexity and cost as well make a semiconductor package thicker. Third, many semiconductor packages have terminals that are exposed on only one surface of the package.

### SUMMARY

This application relates to semiconductor packages that contain leads with multiple terminals. The leads have a side terminal that can extend between a top terminal and a bottom terminal. The multiple terminals in the leads allow the semiconductor package to be connected to more than one external substrate and give the package multiple land pattern options. The semiconductor package can contain one or more dies that are connected to a lead frame in the package without the use of a clip.

### BRIEF DESCRIPTION OF THE DRAWINGS

The following description can be better understood in light of several Figures, in which:

FIG. 1 contains a top perspective view of some embodiments of a semiconductor package;

FIG. 2A contains a top perspective view of some embodiments of a semiconductor package;

FIGS. 2B and 2C each contain a bottom perspective view of some embodiments of a semiconductor package;

FIG. 3 contains a diagram of an equivalent circuit in some embodiments of a semiconductor package;

FIG. 4A contains an illustration depicts one example of die configuration in some embodiments of a semiconductor package;

FIG. 4B contains a left side view of one embodiment of an integrated circuit die in some embodiments of a semiconductor package;

FIG. 5A contains a top side view of embodiment of some embodiments of a semiconductor package;

FIGS. 5B, 5C, and 5D each contain a cross-sectional view of some embodiments of a semiconductor package;

FIGS. 6A and 6B contain a top and bottom perspective view of some embodiments of a lead frame in a matrix form that can be used in a semiconductor package;

FIGS. 7A and 7B contain a top and bottom perspective view of some embodiments of a lead frame in singulated form that can be used a semiconductor package;

FIGS. 8A, B and C contain side views of some embodiments of a semiconductor package with two MOSFET dies;

FIGS. 9A, 9B, 9C, and 9D contain perspective views of an assembly process for some embodiments of a semiconductor package;

FIGS. 10A, B, C, and D contain side views of some embodiments of a semiconductor package;

FIGS. 11A and 11B contain a top perspective view and a bottom perspective view of some embodiments of a semiconductor package;

FIGS. 12A and B illustrate one land pattern in some embodiments of a semiconductor package;

FIGS. 13A and B illustrate another land pattern in some embodiments of a semiconductor package;

FIGS. 14A and B contain views FIGS. 12A and B illustrate one land pattern in some embodiments of a semiconductor package that can be used in a dual PCB assembly;

FIGS. 15 and 16 contains view of some embodiments of package mounting orientations;

FIGS. 17A and B illustrate some embodiments of semiconductor packages used with an external heat sink.

Together with the following description, the Figures may help demonstrate and explain the principles of the invention. Together with the following description, the Figures demonstrate and explain the principles of the semiconductor packages and associated methods. In the drawings, the thickness of layers and regions are exaggerated for clarity. It will also be understood that when a layer is referred to as being “on” another layer or substrate, it can be directly on the other layer or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the semiconductor devices and methods for making and using such devices can be implemented and used without employing these specific details. For example, while the description focuses on semiconductor devices, it can be modified to be used in other electrical devices that are packaged in a similar manner as semiconductor devices. For example, while the following description discusses connecting the semiconductor package to an external substrate, such as a PCB, it may be connected to a ceramic substrate or any other substrate that uses a compatible electrical interconnection layout.

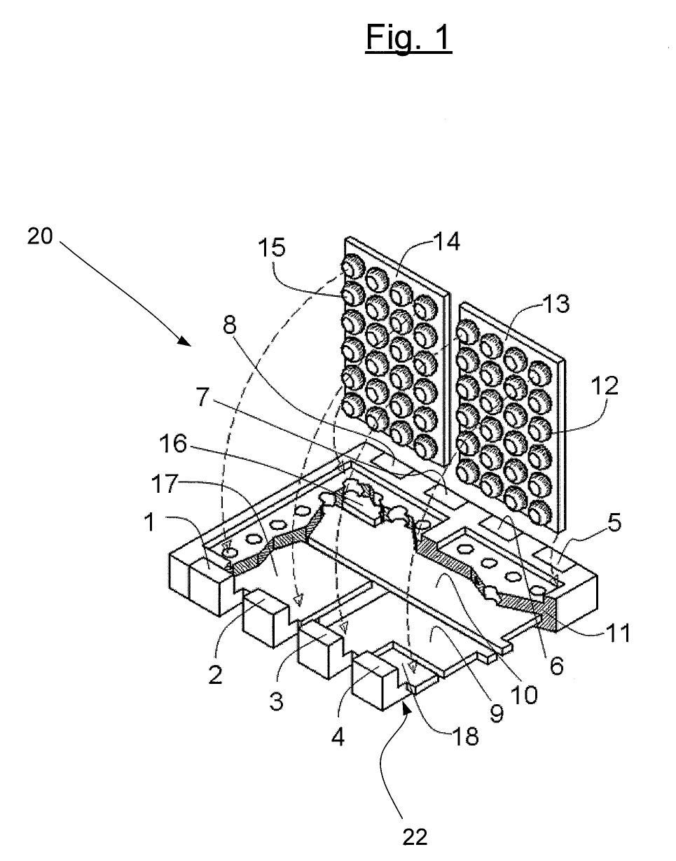

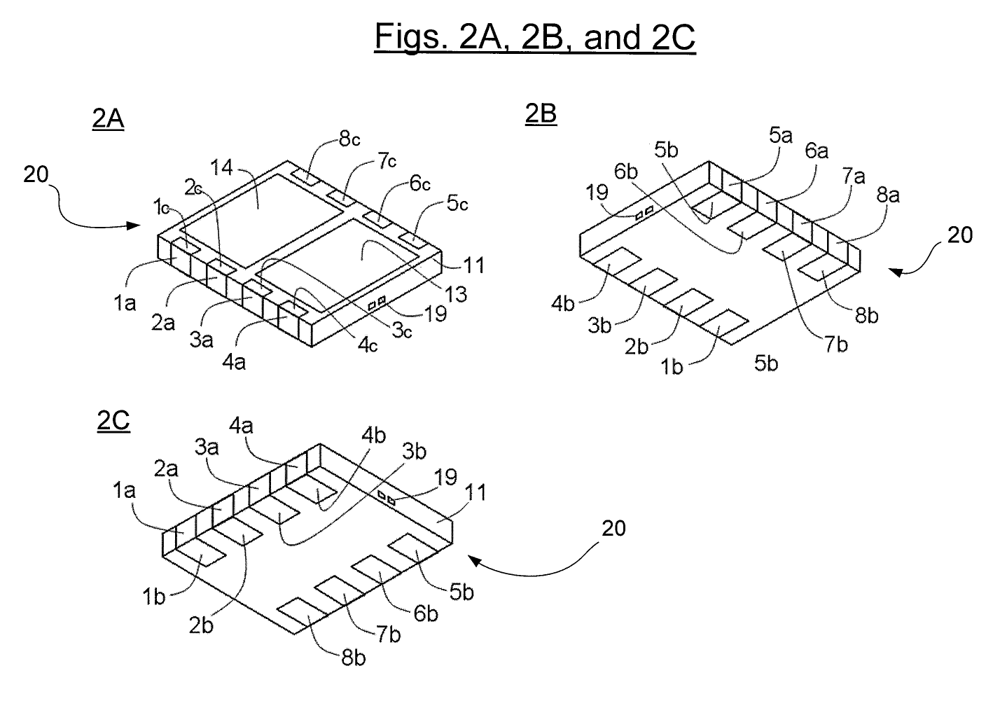

The semiconductor packages contain leads with multiple terminals that are exposed on different sides of the packages. FIG. 1 shows some embodiments of a semiconductor package 20 before it is assembled. FIG. 1 depicts that the package 20 may comprise at least one integrated circuit die (e.g., 13 and 14) with solder bumps (e.g., 12 and 15); a lead frame 22 that may comprise a die pad and leads (e.g., 1-8); as well as a molding material 11, which is depicted in FIG. 1 as being partially cut away. FIG. 1 illustrates that the die pad of the lead frame 22 may comprise bump attach pads, such as the bump attach pads 9, 10, 16, 17, and 18. FIGS. 2A, 2B, and 2C illustrate some of these components of package 20 once the package 20 has been assembled.

The semiconductor package 20 may include at least one integrated circuit die (or die). Indeed, the package 20 may comprise any number of integrated circuit dies suitable for a leadless semiconductor package. For instance, the multi-terminal package 20 may comprise one, two, or even more dies. FIG. 2A illustrates that, in some embodiments, the package 20 may comprise a first (or high side) die 13 and a second (or low side) die 14.

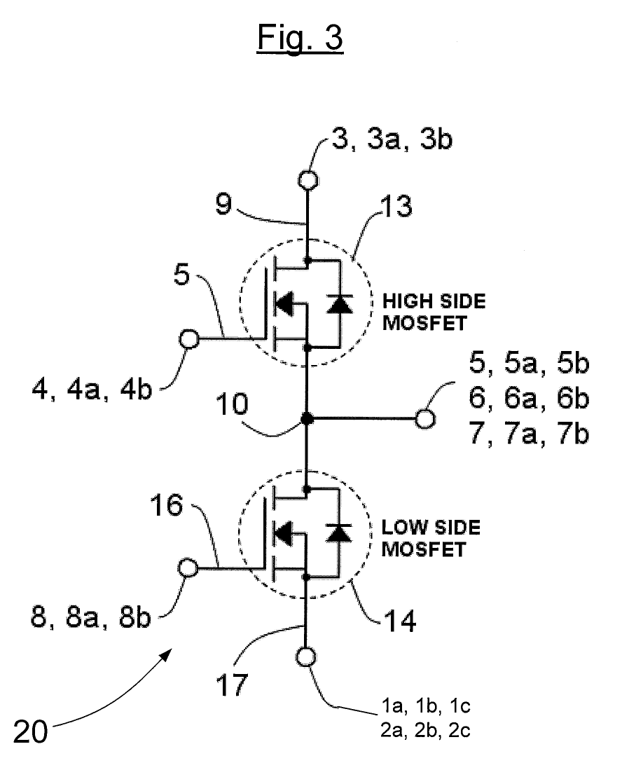

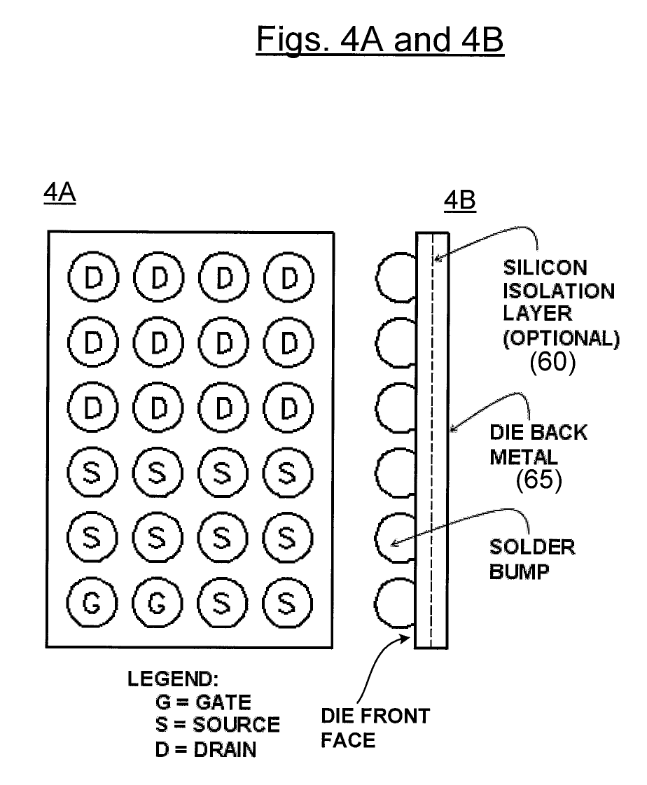

The die included in the package 20 may have any characteristic suitable for use in a semiconductor package. For example, the die may be made of any suitable semiconductor material. Some non-limiting examples of semiconductor materials may include silicon, polysilicon, gallium arsenide, silicon carbide, gallium nitride, silicon and germanium, and the like. Similarly, a die may contain any suitable integrated circuit or semiconductor device. Some non-limiting examples of these devices includes diodes, transistors like BJT (bipolar junction transistors), metal-oxide-semiconductor field-effect transistors (MOSFET) including vertical MOSFETs with a trenched gate, insulated-gate field-effect transistors (IGFET), and other transistors known in the art. FIG. 1 illustrates that the die 13 and the die 14 may comprise a high side MOSFET die and a low side MOSFET die. And FIG. 3 depicts the equivalent circuit of the package 20.

Where the package 20 comprises one or more dies, each die may have any desired characteristic. For example, the die 13 contains the drain, source, and gate regions of the exemplary transistor. The location of the drain regions are shown by the letter D, the location of the source regions are shown by the letter S, and the location of the gate regions are shown by the letter G in FIG. 4A. In some embodiments, these regions are the source, drain, and gate of a MOSFET device(s). The die 14 can be configured similarly.

Each or both dies can contain, as shown in FIG. 4B, an optional isolation layer 60 located within the die itself. The isolation layer 60 can be made of any isolating material, including a silicon oxide isolation layer. Both the lower and upper dies also contain an active layer where the bumps are connected, and an isolated die back layer 65. The die back surface layer 65 can be made with a defined metal plated area that will provide reliable adhesion to surface to which it is attached. Some non-limiting examples of plating used in this plated area includes TiNiAgAu and TiNiAgSn.

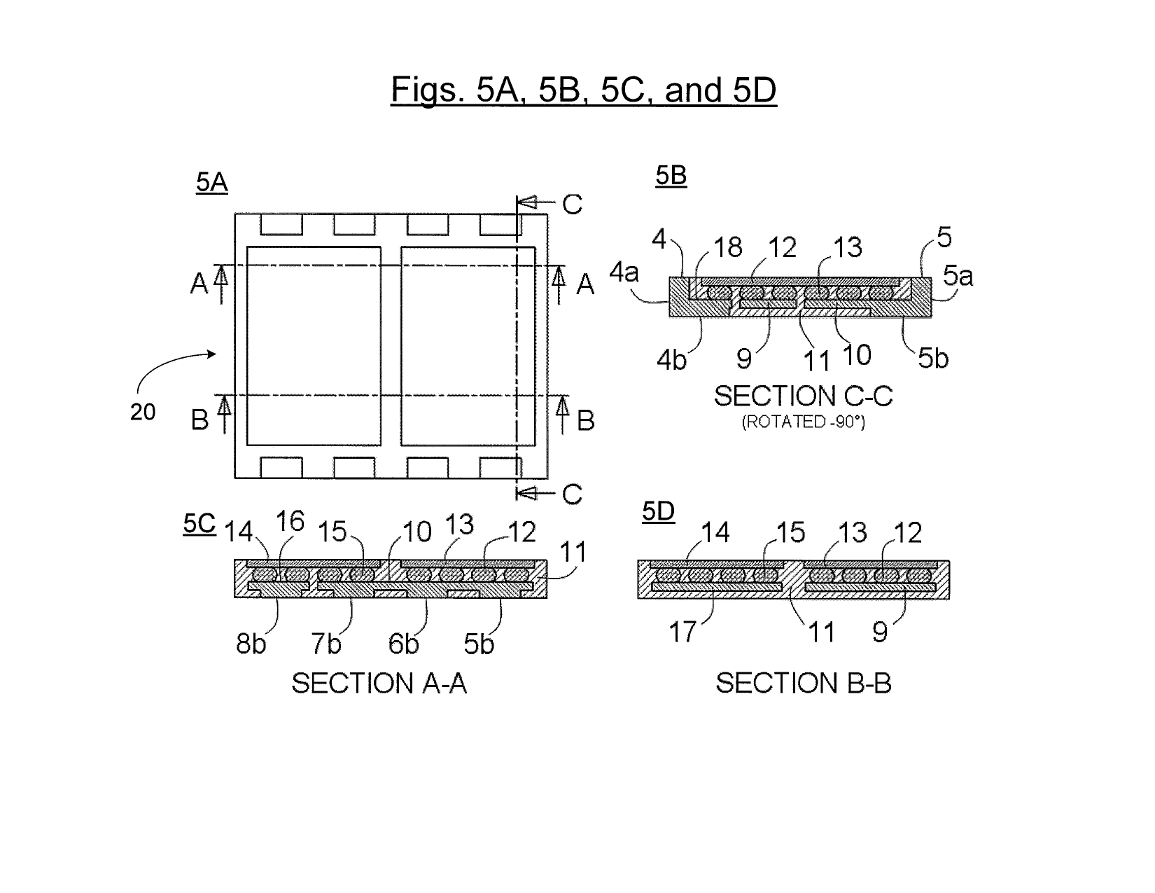

The source, drain, and gate regions (G, S, and D) located on the front face of the dies may be electrically and/or mechanically attached to other components of the package 20 through any appropriate method or technique known in the art. In some embodiments, the G, S, and D regions may be connected to the appropriate bump attach pads 9, 10, 16, 17, and/or 18 of the lead frame 22 through the use of solder bumps, balls, or studs (collectively referred to as solder bumps 12 and 15). In these embodiments, FIGS. 5B, 5C, and 5D show that when the package 20 is assembled so the front face of the dies 13 and 14 are oriented downward, the solder bumps 12 and 15 may extend from the dies 13 and 14, through the molding material 11, and then contact the bump pads 9, 10, 16, 17, and 18.

Where solder bumps are used to connect the die regions G, S, and D to the bump attach pads (e.g., 9, 10, 16, 17, and 18), any known solder bump or conductive bonding material may be used. Some non-limiting examples of solder bumping may include lead-based bumping, lead-free bumping, copper bumping, electroless NiAu bumping, SnPbAg, PbSn, or SnSb bumps. Additionally, a suitable electrically conductive epoxy bonding material may be used and dispensed to the bump attached pads area in replacement of solder bumps to attach a bumpless die, and non-limiting examples of suitable electrically conductive bonding materials may include lead/tin solder paste, silver filled epoxy, tin/silver/copper, and other lead free solders.

The die regions G, S, and D of the die may be configured in any manner that allows them to be electrically connected with their corresponding bump attach pads and terminals, as described hereinafter. For example, FIG. 4A illustrates some embodiments of a MOSFET die where the die regions G, S, and D are configured to contact corresponding bump attach pads. However, the die regions G, S, and D may have different configurations depending on the bump attach pads (and terminals) used in the package 20. Additionally, while FIG. 4A illustrates that the die may have 2 die gate regions, 10 die source regions, and 12 drain regions, the dies may be configured any needed number and configuration of die regions G, S, and D.

The package 20 may also comprise a leadframe 22. The leadframe 22 supports the dies, serves as part of the I/O interconnection system, and also provides a thermally conductive path for dissipating the majority of the heat generated by the dies. The lead frame 22 may have any component or characteristic that allows the dies to be electrically connected to the substrate of an external device. The material of the leadframe 22 may comprise any metal, such as copper or a copper alloy. In some instances, the leadframe 22 can contain a layer of metal plating (not shown), if desired. The layer of metal plating may comprise NiPdAu or may comprise an adhesion sublayer, a conductive sublayer, and/or an oxidation resistant layer. For example, the leadframe structure 50 may include a leadframe plating containing an adhesion sublayer and a wettable/protective sublayer. Additionally, the lead frame 22 may be electroplated or otherwise coated with a layer of a solderable conductive material, such as tin, gold, lead, silver, and/or another solderable material.

The lead frame 22 may also have one or more recesses that define the die pad (or attach pad). For instance, the top surface of the lead frame 22 may have one or more recesses sized and shaped to allow one or more dies to be disposed therein. Where a die (e.g., 13 and/or 14) is disposed in the recess in the top surface of the lead frame 22, the front face of the die may face down towards the lead frame 22 and the back side of the die may be facing up, away from the lead frame 22. Additionally, the bottom surface of the lead frame 22 may have a recess. The recess in the bottom surface of the lead frame 22 may serve many purposes. For example, the recess in the bottom surface of the lead frame 22 may allow the bottom surface of the die pad in the lead frame 22 to remain above the surface of the external substrate, so the bottom surface of the lead pad does not directly contact the external substrate.

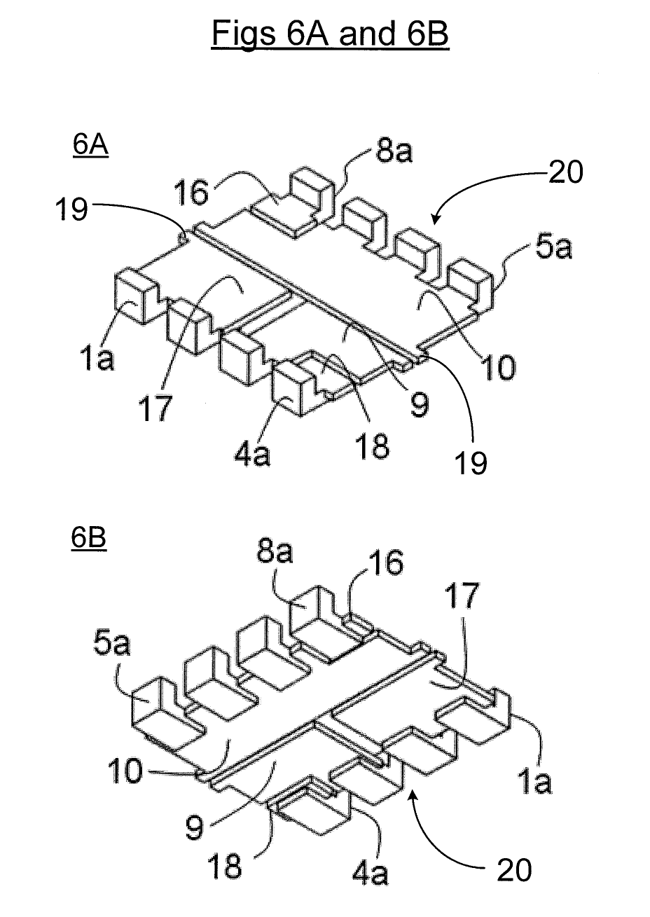

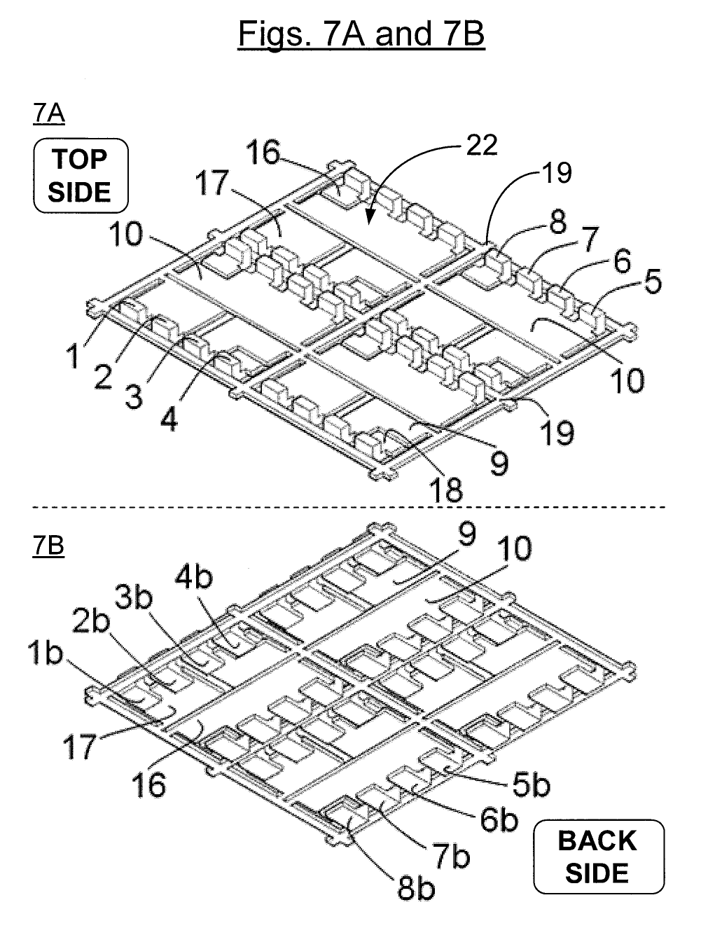

Even though the lead frame 22 may comprise many components, FIGS. 6A and 7A depict different configurations of the lead frames 22. These Figures illustrate that in some embodiments the lead frame 22 may contain a die pad, which includes bump attach pads (e.g., 9, 10, 16, 17, and 18), leads (e.g., 1, 2, 3, 4, 5, 6, 7, and 8), and tie bars 19. The die pad includes—and may be made up of—bump attach pads (e.g., 9, 10, 16, 17, and 18). The lead frame 22 may contain any number of bump attach pads, in any suitable configuration, with any characteristic suitable to electrically connect the solder bumps 12 and 15 from die regions G, S, and D with their appropriate leads (e.g., 1-8, as described hereinafter). For instance, FIG. 6A illustrates that the lead frame 22 may comprise a source bump attach pad 9, a common bump attach pad 10, a drain bump attach pad 17, and two gate bump attach pads 16 and 18. The various bump attach pads 9, 10, 16, 17, and 18 may be electrically isolated from each other in any manner that is known in the art. For example, the bump attach pads 9, 10, 16, 17, and 18 may be spatially and electrically separated from each other by being spaced from each other with a non-conductive material, such as a molding material, in between them.

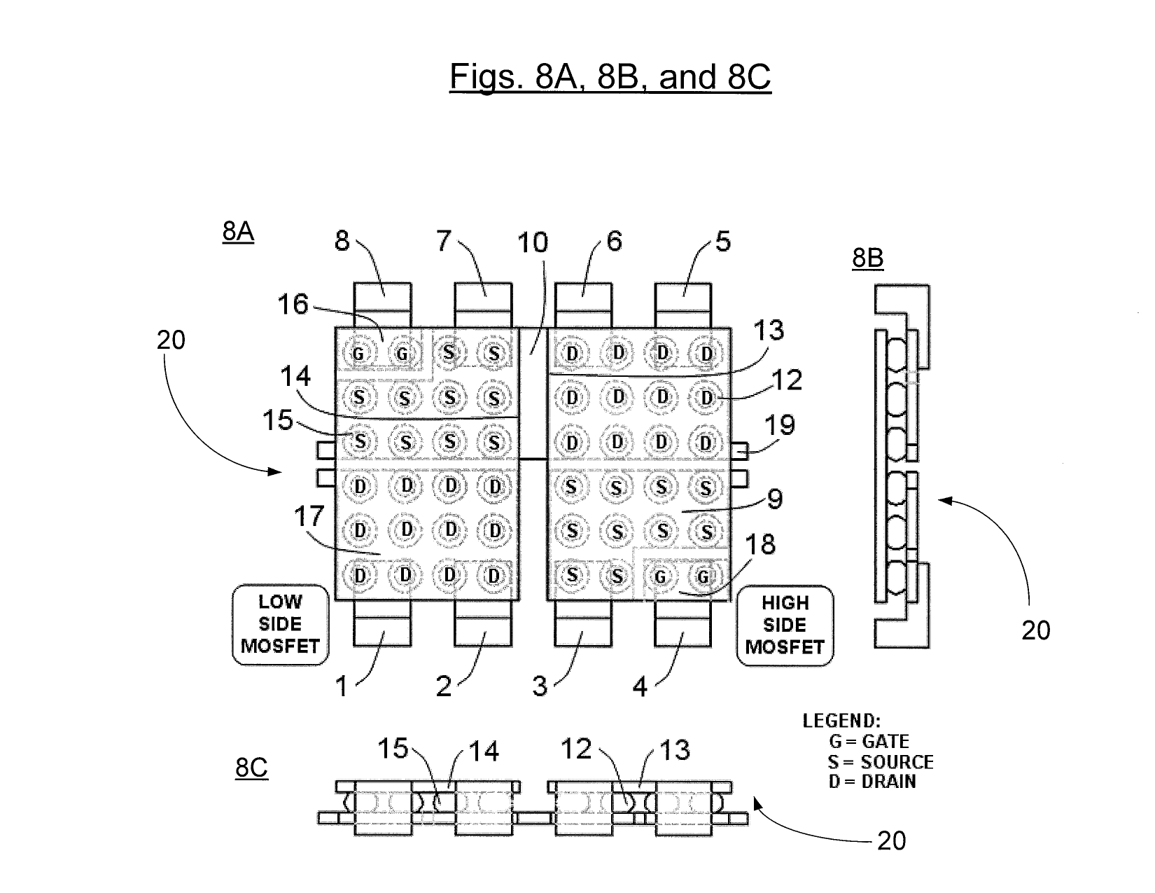

The bump attach pads (e.g., 9, 10, 16, 17, and 18) electrically connect the solder bumps 12 and 15 from the die regions G, S, and D to their corresponding leads (with terminals) located at the edges on a perimeter of the package 20 in any suitable manner. For example, FIGS. 1 and 8A illustrate that where the semiconductor package 20 comprises a high side die 13 and a low side die 14, the source bump attach pad 9 may be used to connect the die source S of the high side die 13—and corresponding solder bumps 12—to the source lead 3. Similarly, the common bump attach pad 10 may serve to electrically connect the solder bumps 12 connected to the drain regions D of the high side die 13 and the solder bumps 15 connected to the source regions S of the low side die 14 to the common leads 5, 6, and 7. The drain bump attach pad 17 may serve to electrically connect the die drain regions D from the low side die 14 to the low side drain leads 1 and 2. And the low side gate bump attach pad 16 may serve to connect solder bumps 15 from the die gate regions G to the low side gate lead 8. Finally, the high side gate bump attach pad 18 may electrically connect the solder bumps 12 connected to the die gate regions G of the high side die 13 to the high side gate lead 4.

The lead frame 22 contains a plurality of leads (e.g. 1-8) disposed about the perimeter of the lead frame 22. The package 20 may have any desired number of leads with any desired characteristic. In some embodiments, FIG. 1 illustrates that the package 20 may have eight leads 1-8. Nevertheless, one of skill in the art will understand that the package 20 may comprise more or less leads than eight. Additionally, one of skill in the art will recognize that the semiconductor package may comprise both active and dummy leads, where active leads are electrically connected to the die(s) in an assembled package 20 and dummy leads are electrically isolated from the die(s). The leads (e.g., 1-8), may be disposed about the perimeter of the multi-terminal package 20 in any desired manner. FIG. 1 shows that the leads 1-8 may be evenly spaced on a front and rear edge of the package 20 in some embodiments. However, in other embodiments, the leads may be located (both evenly and unevenly) on all one to four edges of the perimeter of the package 20.

The leads may have any configuration that allows the package 20 to be electrically connected to any external electronic device. FIG. 1 illustrates that the embodiments where the package 20 comprises both a high side MOSFET die 13 and a low side MOSFET die 14, the low side drain leads 1 and 2, the high side source lead 3, and the high side gate lead 4 may all be located on the front edge of the package 20. The common leads 5, 6, and 7 for both the high side die drain regions D and the low side die source regions S may be located on the rear edge of the package 20, along with the low side gate lead 8.

The leads contain at least three terminals for electrically and/or mechanically connecting the package 20 to an external electric device. FIGS. 2A, 2B, and 2C show some embodiments of the package 20 comprising leads 1-8 with multiple terminals that are externally exposed from the package 20. FIG. 2A shows that a leads 1-8 may be externally exposed on the top and therefore contain top terminals 1c through 8c. FIGS. 2B and 2C show that the leads 1-8 on the package 20 may have a side terminal (respectively 1a through 8a) that may be exposed on the side of the package 20. Similarly, FIGS. 2B and 2C illustrate that that the bottom surfaces of the active leads 1-8 may each have a bottom terminal 1b through 8b.

The top terminals 1c-8c, side terminals 1a-8a, and bottom terminals 1b-8b of the leads 1-8 may have any configuration that allows them to be electrically and/or mechanically connected to an external device. For instance, the top 1-8, side 1a-8a, and bottom 1b-8b terminals of the leads 1-8 may have any coating or have any shape or size, including that illustrated in FIGS. 2A, 2b, and 2C where the terminals and have a surface area that appears to be substantially square or rectangular.

The top 1c-8c, side 1a-8a, and bottom 1b-8b terminals may be substantially similar or substantially different in size and appearance. The exact shape and size will be determined, in part, by the portion of the external device to which they will serve as a connection, i.e., they may be sized and shaped to be electronically connected an exterior substrate with traces (e.g., copper traces) of corresponding sizes and shapes. For example, FIGS. 2A, 2B, and 2C illustrate that in some embodiments the top terminals 1c-8c may be smaller in size than the bottom terminals 1b-8b. FIGS. 2A, 2B, and 2C also illustrate that the side terminals 1a-8a may extend substantially between the top terminal 1c-8c and the bottom terminal 1b-8b—or the top surface and the bottom surface—of the package 20. And although the side terminals 1a-8a may extend at any angle to their corresponding top terminals 1c-8c and bottom terminals 1b-8b, FIG. 2A illustrates that the side terminals 1a-8a may run substantially orthogonal to the top 1-8 and the bottom terminals 1b-8b. Accordingly, unlike some step-shaped leads known in the art, the terminals may give the leads 1-8 a non-step shaped configuration.

The top 1c-8c, side 1a-8a, and bottom 1b-8b terminals may have any other feature suitable for lead terminals in a semiconductor package. In some embodiments, some or all of the terminals 1c-8c, 1a-8a, and 1b-8b may comprise lead intrusions and/or depressions. Such lead intrusions and depressions may serve to increase the solder or bonding material joint strength between the package 20 and a substrate of an external device. In other embodiments, the lead terminals 1c-8c, 1a-8a, and 1b-8b may be electroplated or otherwise coated with a conductive material such as silver, gold, tin, aluminum, lead, etc. . . .

In some embodiments, the lead frame 22 may also include tie bars 19 as are commonly known in the art. Indeed, the package 20 may have any number of known tie bars 19 with any desired feature. For example, FIG. 6A illustrates that the tie bars 19 may extend from the source bump attach pad 9, the common bump attach pad 10, and the drain bump attach pad 17. Similarly, FIG. 7A illustrates that tie bars 19 may extend between individual lead frames 22 when multiple lead frames 22 are connected together in a matrix.

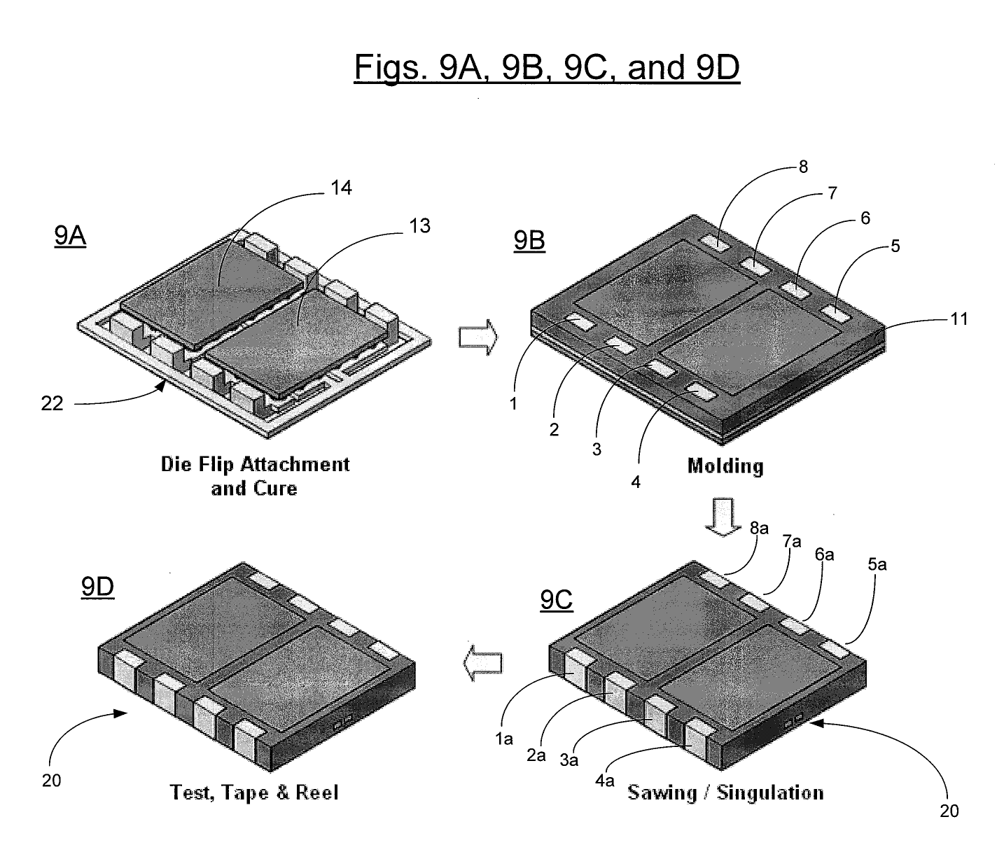

The semiconductor packages described above can be made using any suitable method that forms the structures illustrated. In some embodiments, FIGS. 9A, 9B, 9C, and 9D illustrate one typical method for assembling a package 20. First, the dies for the first and second dies are first provided with the isolation layer 60. Isolation layer 60 can be provided at wafer level manufacturing, including the die back 65 surface plating. Then, the various electronic components (i.e., the transistors) are manufactured, an array of bonding pads then provided, solder bumped, cut, tested, and die-bonded to a substrate as known in the art to form the die 13 and the die 14.

Next, the leadframe 22 (as shown in FIGS. 7A and 7B) is formed by any known method, for example, metal stamping and etching processes. If desired, a layer of metal plating may be formed on the base metal used in the leadframe by processes such as electroless plating, sputtering, or electroplating. A pre-plated leadframe can also be used instead.

Then, the solder bumps 12 are then provided in the desired locations of the die 13, i.e., those where the bond pads are located or over where the source, drain, and gate regions of the MOSFET are located. The solder bumps 12 can be provided using any mechanism known in the art. In some instances, the solder bumps 12 can be instead provided on the die attach pad of the leadframe 22 as known in the art. The solder bumps 15 can similarly be provided in the desired locations of the die 14 during the same process or in a different process, or the solder bumps can be attached to the die active area during wafer level manufacturing.

Next, the dies 13 and 14 are then flip-attached to the die attach pad of the leadframe 22 as shown in FIG. 9A. In this process, the solder bumps become attached to the leadframe and thereby attach the dies to the structure of the leadframe. In this process, the structure is heated in a defined temperature reflow profile. During the heating process, the solder bumps will melt to form solder joints and a die position stand-off will be established when the resulting structure is cooled down. In this attachments process, the die gate regions G, die source regions S, and die drain regions D, with their respective solder bumps 12 and 15, may align with and contact their respective bump attach pads (e.g., 9, 10, 16, 17, and 18).

After the attachment of the dies 13 and 14, FIG. 9B depicts that the lead frame 22 and desired components may be encapsulated in a molding material 11. The molding material 11 used in these embodiments can comprise any molding material known in the art that flows well and therefore minimizes the formation of any gaps. In some aspects, the molding material comprise an epoxy molding compound such as an epoxy material with a low thermal expansion (a low CTE), fine filler size (for good flow distribution of the molding material), and high adhesion strength. Some non-limiting examples of suitable molding materials 11 may include thermoset resins—such as silicones, phenolics, and epoxy mold compounds—and thermoplastics. Moreover, the molding material 11 may be formed around the desired components in any suitable process known in the art.

FIG. 9B shows that in some embodiments, the top terminals 1c-8c, side terminals 1a-8a, and the bottom terminals (not shown in the Figure) of the leads 1-8 may be externally exposed after the molding process. FIG. 9B shows that in some embodiments, the back side of the dies 13 and/or 14 may be not be encapsulated and therefore remains exposed from the molding material 11.

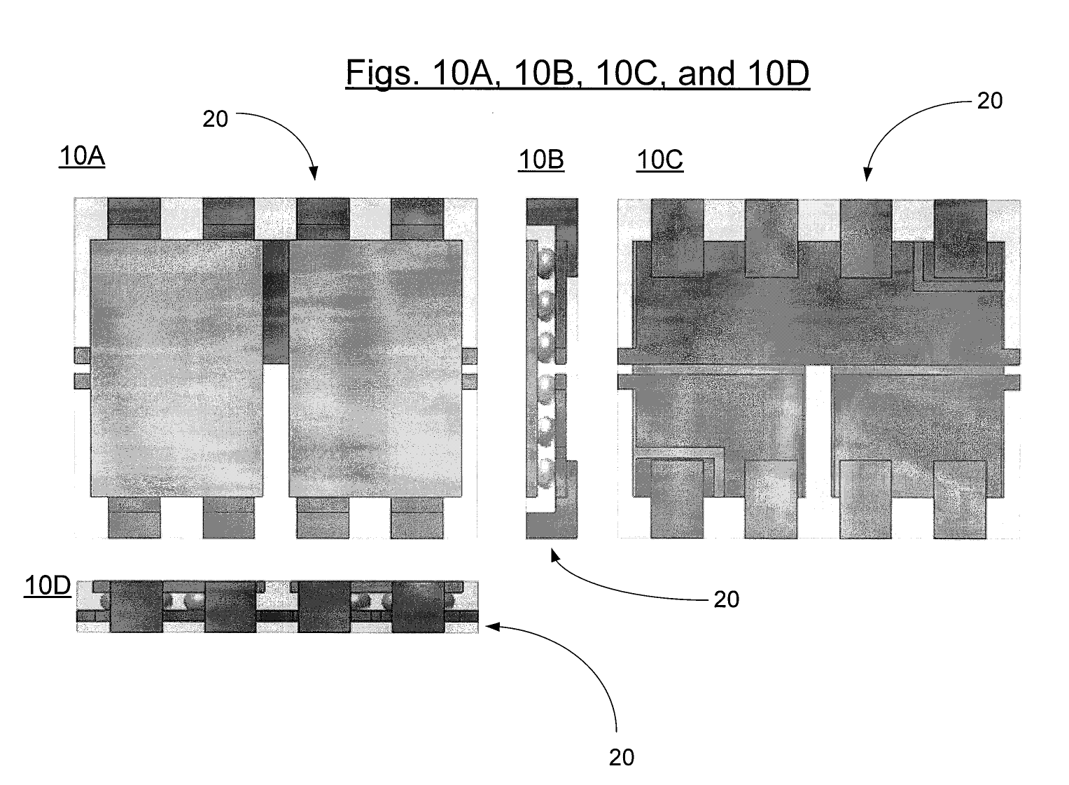

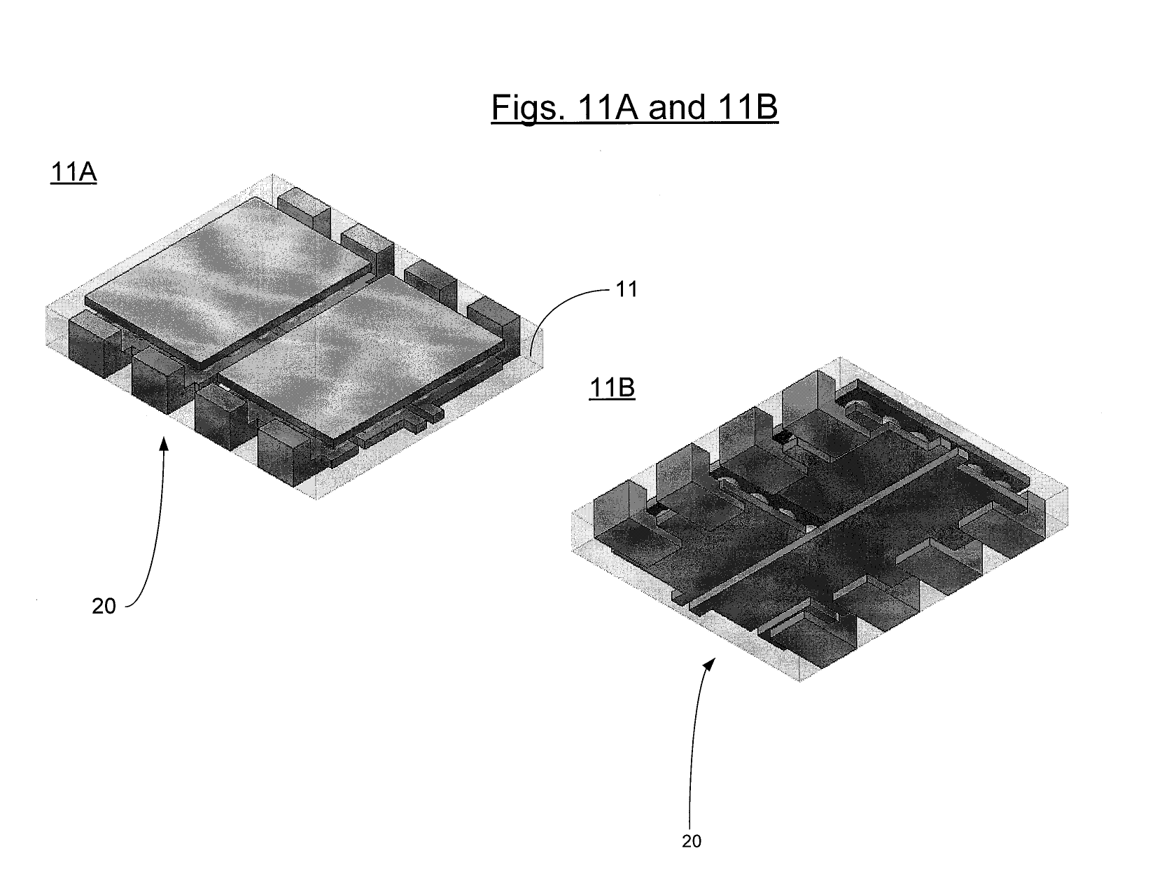

Once these processes are performed, the devices are singulated as known in the art. FIG. 9C shows some embodiments of a singulated package where the side terminals 1a-8a are externally exposed. Some non-limiting examples of methods for singulation may include saw singulation or punch singulation, as are commonly known in the art. Then, the singulated semiconductor packages may be electrically tested. After electrical testing, the top surface the semiconductor packages may be laser marked according to the device code and index marked for orientation indication. Finally, the devices may be taped and reeled as known in the art, as illustrated in FIG. 9D. FIGS. 10A, 10B, 10C, 10D, 11A, and 11B illustrate several views of the package 20 after it has been assembled, encapsulated, and singulated.

The semiconductor packages 20 described above have several features. First, the package 20 allows for a small amount of copper (or other conductive material) to be used when connecting the solder bumps 12 and 15 from the die 13 and 14 to the proper bump attach pads 9, 10, 16, 17, and/or 18. Accordingly, the package 20 allows for lower R_{DS} than conventional wire bonding semiconductor packages.

Second, the use of die 13 and/or die 14 whose die gate regions G, die drain regions D, die source regions S, and solder bumps 12 and 15 located on the front face of the dies can allow the combination of a high side MOSFET die 13 and a low side MOSFET die 14 to be connected on the lead frame 22 without the use of a conventional clip. Without a clip, the resulting package 20 may be thinner, less complicated, less costly, and have simpler copper trace routing than some other semiconductor packages.

Third, the exposed top 1c-8c, side 1a-8a, and bottom terminals 1b-8b allow the package 20 to be more robust during the molding process. The top 1-8, side 1a-8a, and bottom 1b-8b terminals also help to eliminate mold flashes during the molding process. Moreover, the exposed terminals may also permit the molding process to be accomplished without requiring a film assist.

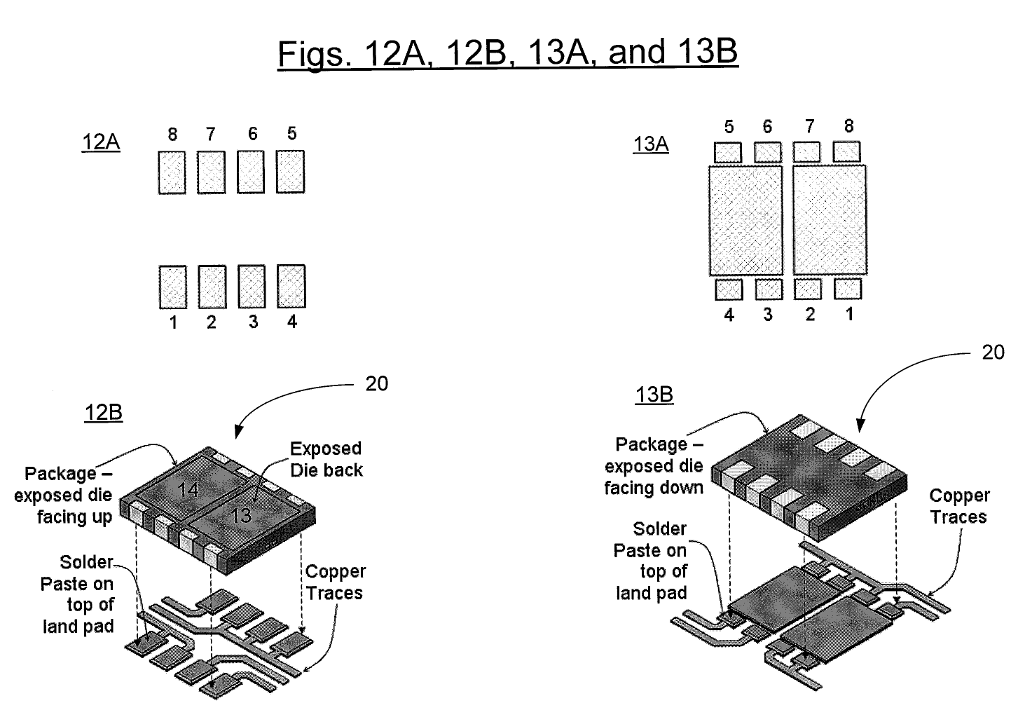

Fourth, FIGS. 12A, 12B, 13A, and 13B illustrate that the multiple terminals allow the package 20 to interconnect with at least two different land pattern options. For example, FIGS. 12A and 12B illustrate that when the package 20 is oriented with the top surface facing up so that the exposed back surfaces of the dies 13 and 14 are facing up, the package 20 may be connected to an exterior surface with a traces in first land pattern option. FIGS. 13A and 13B depict another example where the package 20 is flipped over so that the bottom surface of the package 20 is facing up and the exposed back surfaces of the dies are facing down, the package 20 may be connected to an external substrate with traces in a second land pattern option. Accordingly, this interconnection flexibility allows the package 20 to more easily satisfy the PCB assembly requirements of a user.

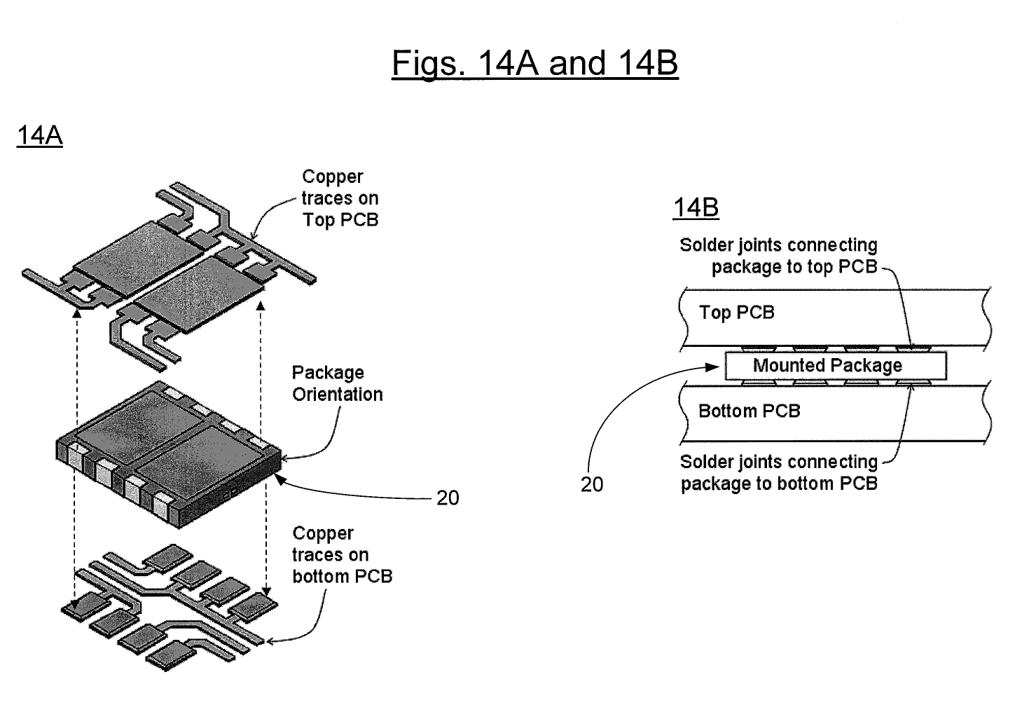

Fifth, the multiple terminals of the package 20 may allow for dual PCB (or other external substrate) connection. For instance, FIGS. 14A and 14B illustrate that the traces of a top PCB may be connected to the top surface of the package 20 at the same time the traces of a bottom PCB may be connected to the bottom surface of the multi-terminal package 20.

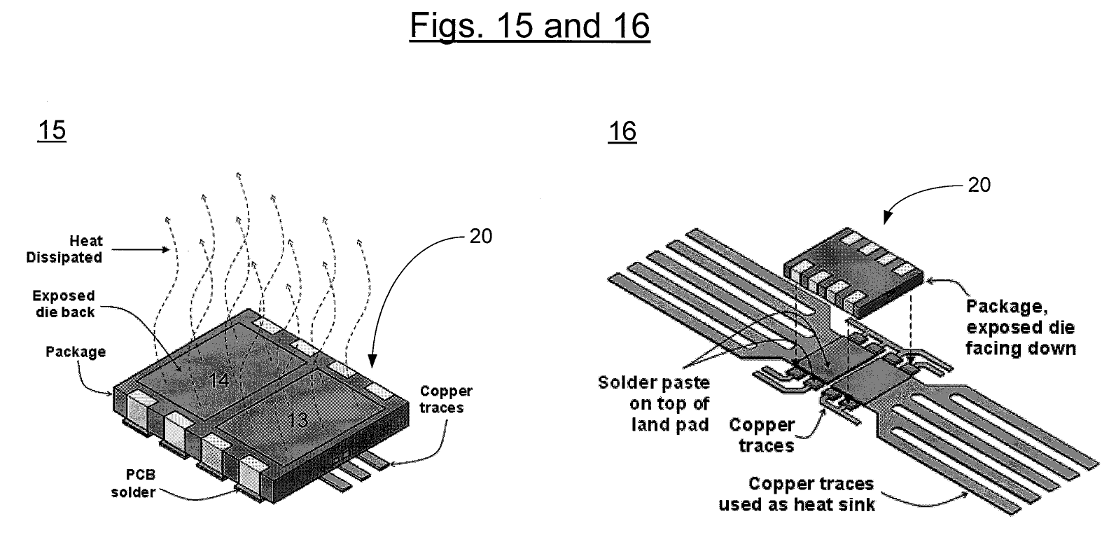

Sixth, the package 20 may allow for better thermal heat dissipation than other semiconductor packages. For example, FIG. 15 illustrates that where the back sides of the dies 13 and 14 are externally exposed from the package, heat may dissipate from the exposed surface of the dies 13 and 14. In another example, FIG. 16 illustrates that where the package 20 is flipped over so the exposed back sides of the dies are facing down, the package 20 may be connected to the PCB so that the back sides of the dies act as a heat sink interface and heat dissipates from the dies into a copper trace.

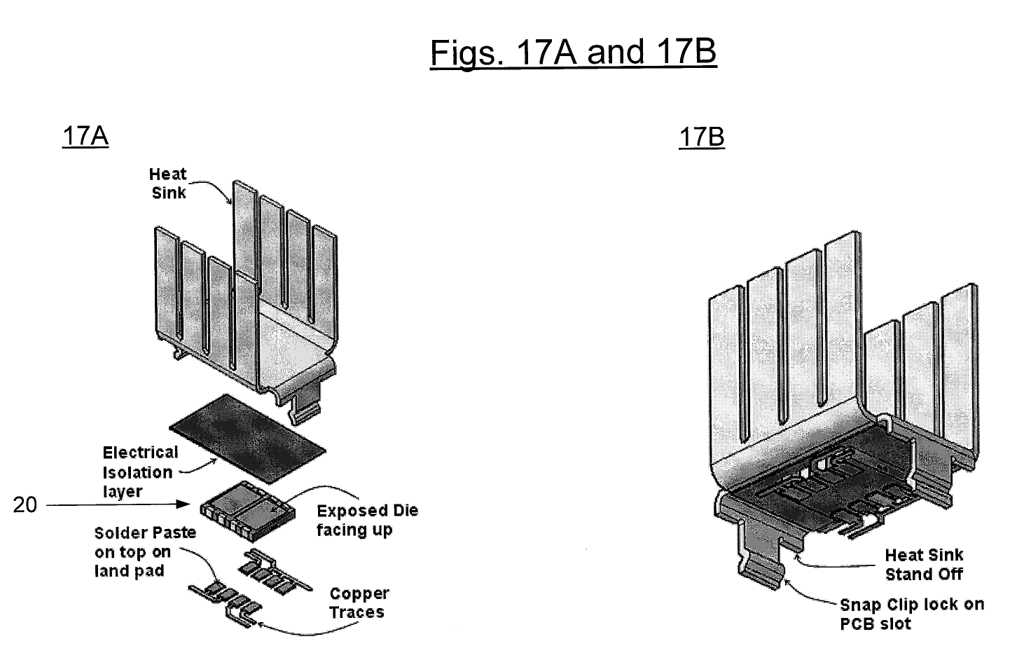

In yet another example of this heat dissipation, FIGS. 17A and 17B illustrate that the exposed back surfaces of dies 13 and 14 may act as a heat sink interface and allow for thermal heat dissipation through an external heat sink. FIG. 17A shows that the exposed back sides of the dies may face up when the package 20 is electrically connected to the traces of a PCB. Between the top surface of the package 20 and the heat sink, an electrical isolation layer made of any suitable material may be provided. Heat that is generated during operation may travel directly through the electrical isolation layer and may then be dissipated by the heat sink. To reduce the amount of heat dissipated to the PCB, in some embodiments the heat sink may comprise one or more heat sink stand offs, as illustrated in FIG. 17B. While the heat sink may be connected to the package 20 in any manner, FIG. 17B illustrates that the heat sink may be connected to the PCB via snap clip locks, which may extend through corresponding slots in the PCB.

The multi-terminal package 20 may be used in any known device or system. Some non-limiting examples of such devices may include a scan driver block, an inverter block, and a DC/DC switcher device with a circuit equivalent to that detailed in FIG. 3.

Having described the preferred aspects of the semiconductor packages and associated methods, it is understood that the appended claims are not to be limited by particular details set forth in the above description, as many apparent variations thereof are possible without departing from the spirit or scope thereof.

1. A semiconductor package, comprising:
a die containing an integrated circuit;
multiple non-step shaped leads that are electrically connected to the integrated circuit, wherein each of the multiple leads comprise a top terminal, a side terminal, and a bottom terminal that are externally exposed from the semiconductor package.

2. The semiconductor package of claim 1, wherein the side terminal substantially extends between the top terminal and the bottom terminal.

3. The semiconductor package of claim 1, further comprising a lead frame contains a die pad on which the die is located.

4. The semiconductor package of claim 3, wherein the die comprises a gate region, a source region, and a drain region on a front face.

5. The semiconductor package of claim 4, wherein the lead frame is connected to the die using solder bumps.

6. The semiconductor package of claim 1, wherein the package contains two dies each containing a MOSFET.

7. The semiconductor package of claim 1, wherein a back side of the die is externally exposed from the package.

8. A semiconductor package, comprising:
a die containing an integrated circuit;
a lead frame containing a die pad on which the die is located, wherein the lead frame is connected to the die using solder bumps; and
leads disposed about a plurality of edges of the package, the leads containing a top terminal, a bottom terminal, and a side terminal that are exposed from the semiconductor package, wherein the side terminal substantially extends between the top terminal and the bottom terminal on the side of the package.

9. The semiconductor package of claim 8, wherein the die comprises a gate region, a source region, and a drain region on a front face.

10. The semiconductor package of claim 8, wherein the package contains two dies each containing a MOSFET.

11. The semiconductor package of claim 8, wherein a back side of the die is externally exposed from the package.

12. The semiconductor package of claim 8, wherein the side terminal extends substantially continuously between the top terminal and the bottom terminal on the side of the package.

13. A method of making a semiconductor package, comprising:
providing a die containing an integrated circuit;
electrically connecting multiple, non-step shaped leads to the integrated circuit die using solder bumps, wherein the leads comprise a top terminal, a side terminal, and a bottom terminal; and
encapsulating the die and leads so that the top terminal, the side terminal, and the bottom terminal of the leads remain exposed from the package.

14. The method of claim 13, wherein the side terminal substantially extends between the top terminal and the bottom terminal.

15. The method of claim 13, further comprising:
providing a lead frame containing a die pad; and
connecting the lead frame to the die using solder bumps.

16. The method of claim 1, wherein the encapsulation also leaves a back side of the die exposed from the package.

17. A method of making a semiconductor package, comprising:
providing a die containing an integrated circuit;
connecting a lead frame containing a die pad to the die using solder bumps;
disposing a plurality of leads on the edges of the package, the leads containing a top terminal, a bottom terminal, and a side terminal; and
encapsulating the die and leads so that the top terminal, the side terminal, and the bottom terminal of the leads remain exposed from the package.

18. The method of claim 17, wherein the encapsulation also leaves a back side of the die exposed from the package.

19. The method of claim 17, wherein the side terminal substantially extends between the top terminal and the bottom terminal.

20. The method of claim 19, wherein the side terminal extends substantially continuously between the top terminal and the bottom terminal on the side of the package.

21. An electrical system containing a semiconductor package, the package comprising:
a die containing an integrated circuit;
a lead frame containing a die pad on which the die is located, wherein the lead frame is connected to the die using solder bumps; and
leads disposed about a plurality of edges of the package, the leads containing a top terminal, a bottom terminal, and a side terminal that are exposed from the semiconductor package, wherein the side terminal substantially extends between the top terminal and the bottom terminal on the side of the package.

22. The system of claim 21, wherein the die comprises a gate region, a source region, and a drain region on a front face.

23. The system of claim 21, wherein the semiconductor package contains two dies each containing a MOSFET.

24. The system of claim 21, wherein a back side of the die is externally exposed from the package.

25. The system of claim 21, wherein the side terminal extends substantially continuously between the top terminal and the bottom terminal on the side of the package.
